(19) United States
(12) Patent Application Publication
(10) Pub. No.: US 2026/0278778 A1
(43) Pub. Date: Sep. 17, 2026

(54) SOLDER FILLET INSPECTING DEVICE AND SOLDER FILLET INSPECTING METHOD

(71) Applicant: CKD Corporation, Aichi (JP)

(72) Inventors: Kazuyoshi Kikuchi, Aichi (JP); Tadanori Hirano, Aichi (JP)

(73) Assignee: CKD Corporation, Aichi (JP)

(21) Appl. No.: 19/674,625

(22) Filed: May 12, 2026

Related U.S. Application Data
(63) Continuation of application No. PCT/JP2024/035942, filed on Oct. 8, 2024.

(30) Foreign Application Priority Data
Dec. 15, 2023 (JP) 2023-211616

(51) Int. Cl. G06T 7/00; G06V 10/774; G06V 10/82

(52) U.S. Cl. CPC G06T 7/001; G06V 10/774; G06V 10/82; G06T 2207/20081; G06T 2207/20084; G06T 2207/30141; G06T 2207/30152

(57) ABSTRACT

A solder fillet inspecting device includes: an imaging device that captures image data of an inspection target area in a printed circuit board that includes a solder fillet formed to solder an electronic component to the printed circuit board; a first Artificial Intelligence (AI) model generated by learning of a neural network using only image data of a non-defective solder fillet as first learning data; and a control device that: obtains, as an inspection object, inspection image data that includes an image of the solder fillet based on the image data captured by the imaging device, obtains reconfiguration image data by inputting the inspection image data into the first AI model, makes a comparison between the inspection image data and the reconfiguration image data, and detects defectiveness/non-defectiveness of the solder fillet based on a comparison result.

### BACKGROUND

### Technical Field

The present disclosure relates to an inspection device and an inspection method for performing an inspection for solder fillet that is used to solder an electronic component.

### Description of Related Art

In general, a board production line for mounting an electronic component on a printed circuit board first prints solder paste on a land of the printed circuit board (a solder printing process). The board production line then tentatively fastens an electronic component on the printed circuit board by taking advantage of the viscosity of the solder paste (a mounting process). The board production line subsequently guides the printed circuit board to a reflow furnace to heat and fuse the solder paste and solder the electronic component (a reflow process). This board production line is often provided with an inspection device configured to perform an inspection for the printed circuit board.

An inspection device using an AI model has recently been proposed as an inspection device configured to perform an inspection for solder paste after a reflow process, i.e., a solder fillet, which is used to solder an electronic component (as described in, for example, Patent Literature 1). This inspection device executes a predetermined inspection program to measure a predetermined index or indication, based on an inspection image and to inspect the conditions of an inspection object by using a measurement value. The inspection program to be executed generates an AI model for each type of an electronic component (for each component type). In many cases, lands which electronic components are mounted on have different sizes according to the types of the electronic components. It is accordingly said that this inspection program is executed to generate different AI models corresponding to respective sizes of lands.

### PATENT LITERATURE

Patent Literature 1: Japanese Patent No. 2022-140951A

The lands have a variety of sizes as mentioned above. Troublesome work is, however, required to generate and provide different AI models for the respective sizes of lands. This is likely to require large amounts of labor, time and effort.

### SUMMARY

By taking into account the circumstances described above, embodiments of the present disclosure provide a solder fillet inspecting device and the like that reduce the labor, the time and the load for obtaining AI models and that enable the AI models to be commonly used for lands of various sizes.

The following describes each of various aspects of the present disclosure. Functions and advantageous effects that are characteristic of each of the aspects are also described as appropriate.

Aspect 1. There is provided a solder fillet inspecting device configured to perform an inspection for a solder fillet, which is used to solder an electronic component to a printed circuit board. The solder fillet inspecting device comprises: an imaging device that captures image data of an inspection target area in a printed circuit board that includes a solder fillet formed to solder an electronic component to the printed circuit board; a first Artificial Intelligence (AI) model generated by learning of a neural network using only image data of a non-defective solder fillet as first learning data, wherein the neural network comprises an encoder configured to extract a feature quantity from input image data and a decoder configured to reconfigure the input image data from the feature quantity; a control device that: obtains, as an inspection object, inspection image data that includes an image of the solder fillet, based on the image data captured by the imaging device, obtains reconfiguration iimage data by inputting the inspection image data into the first AI model, and makes a comparison between the inspection image data and the reconfiguration image data, and detects defectiveness/non-defectiveness of the solder fillet based on a comparison result. The first learning data is generated by placing one solder fillet image that indicates a solder fillet corresponding to one land, in a first image frame having a larger size than a size of the one solder fillet image. The control device obtains the inspection image data that has a size identical with a size of the first learning data and that is generated by placing the one solder fillet image extracted from the image data captured by the imaging device, in an image frame having a size identical with the size of the first image frame for the first learning data.

The one solder fillet image may be an image (an image of Aspect 2 described later) indicating the entirety of a linkage component (block portion) of a solder fillet that is at least partly located on one land or may be an image indicating only part of the linkage component of the solder fillet, which is present on one land. The one solder fillet image may include a land, an electrode and the like located in the periphery of the linkage component, in addition to the linkage component of the solder fillet.

Additionally, the one solder fillet image configuring the first learning data may be an image (an image of an actual solder fillet) extracted from image data (actual image data) that is obtained by taking an image of a printed circuit board provided with a non-defective solder fillet or may be a virtually generated image of a non-defective solder fillet. The actual image data may be, for example, image data accumulated by past inspections or image data of a non-defective printed circuit board that is visually selected by an operator after a reflow process.

Furthermore, the “neural network” described above includes, for example, a convolution neural network having a plurality of convolution layers. The “learning” described above includes, for example, deep learning. The “first AI model (identification unit or generation model)” described above includes, for example, an autoencoder and a convolution autoencoder.

Additionally, the “first AI model” is generated by learning of the neural network using only the image data of a non-defective solder fillet (i.e., learning data provided by placing one solder fillet image with regard to a non-defective solder fillet in a first image frame). This causes reconfiguration image data that is generated by inputting inspection image data of a defective solder fillet into the first AI model, to be substantially equal to inspection image data with correction of a defective portion (for example, appropriate correction of the shape or the area). In the case where a solder fillet has any defective portion, this configuration accordingly causes virtual image data of a solder fillet with the assumption of no defective portion to be generated as the reconfiguration image data of this defective portion-including solder fillet.

In the solder fillet inspecting device of above Aspect 1, inspection image data is obtained by placing one solder fillet image extracted from the image data captured by the imaging device, in the first image frame. The size (the width and the height) of the inspection image data is thus not minutely varied according to the size of the land but is fixed. There is accordingly no need for providing a large number of different AI models corresponding to different sizes of lands. This configuration reduces the labor, the time and the effort of providing the first AI model. This configuration also enables the first AI model to be commonly used for the lands of various sizes.

Furthermore, in the solder fillet inspecting device of above Aspect 1, the size of the first image frame for the first learning data is equal to the size of the image frame for the inspection image data, and the size of the first learning data is equal to the size of the inspection image data. When the inspection image data is input into the first AI model, this configuration accordingly enables the appropriate reconfiguration image data corresponding to the inspection image data to be more certainly output from the first AI model and thereby ensures the more accurate defectiveness/non-defectiveness detection of the solder fillet. This more reliably ensures the high inspection accuracy.

Moreover, the solder fillet inspecting device of above Aspect 1 makes the comparison between the inspection image data and the reconfiguration image data that is reconfigured by inputting the inspection image data into the first AI model, and detects defectiveness/non-defectiveness of the solder fillet based on the comparison result. Accordingly, these two image data to be compared with each other are related to one identical solder fillet. Unlike a technique of detecting defectiveness/non-defectiveness by a comparison with a separately provided standard or criterion, this configuration does not need to set relatively mild inspection conditions for the purpose of preventing an erroneous inspection, but allows for setting the stricter inspection conditions. Furthermore, the same imaging conditions for the printed circuit board as an inspection object (for example, the layout position, the layout angle, and the deflection of the printed circuit board) and the same imaging conditions of the solder fillet inspecting device (for example, the illumination conditions and the angle of view of a camera) may be employed for both these two image data to be compared with each other. These, in combination, enable detecting the defectiveness/non-defectiveness of the solder fillet with the higher accuracy.

Aspect 2. In the solder fillet inspecting device described in above Aspect 1, the control device may extract the one solder fillet image that constitutes the inspection image data, from the image data captured by the imaging device. The control device may specify an area occupied by a solder fillet in the image data captured by the imaging device and extract an image of a linkage component in the specified area, as the one solder fillet image that constitutes the inspection image data.

In the solder fillet inspecting device of above Aspect 2, the control device specifies an area occupied by a solder fillet in the image data captured by the imaging device, and extracts an image of a linkage component in the specified area, as one solder fillet image configuring inspection image data. Accordingly, one solder fillet image includes not only an image of a portion of a solder fillet located on a land but an image of a portion of the solder fillet partly protruded from the land. More specifically, even when a solder fillet 5 is partly protruded from a land 3 as shown in FIG. 27, one solder fillet image Ih includes this protruded portion as shown in FIG. 28. This configuration enables detecting the defectiveness/non-defectiveness adequately with regard to the solder fillet partly protruded from the land and thereby further enhances the inspection accuracy.

Aspect 3. The solder fillet inspecting device described in above Aspect 1 may further comprise a second AI model generated by learning of a neural network using only image data of a non-defective solder fillet as second learning data, wherein the neural network comprises an encoder configured to extract a feature quantity from input image data and a decoder configured to reconfigure the input image data from the feature quantity. The second learning data may be generated by placing the one solder fillet image in a second image frame having such a size that is larger than the size of the one solder fillet image and that is smaller than the size of the first image frame for the first learning data. In the case where the size of the one solder fillet image extracted from the image data captured by the imaging device is smaller than the size of the second image frame, the control device: obtains the inspection image data that has a size identical with a size of the second learning data and that is generated by placing the one solder fillet image in the second image frame, obtains the reconfiguration image data by inputting the obtained inspection image data into the second AI model, and makes the comparison between the inspection image data and the reconfiguration image data.

In the solder fillet inspecting device of above Aspect 3, in the case where the one solder fillet image has a relatively small size, the control device obtains the inspection image data of a relatively small size by placing the one solder fillet image in the second image frame of a relatively small size. The control device causes relatively small reconfiguration image data to be output from the second AI model by inputting this relatively small inspection image data into the second AI model. The control device then makes a comparison between the relatively small inspection image data and the relatively small reconfiguration image data. Compared with a configuration of using a fixed size of an image frame for any inspection image data, this configuration speeds up the process of obtaining the reconfiguration image data and the comparison process and thereby further increases the inspection speed.

Aspect 4. In the solder fillet inspecting device described in above Aspect 1, the first learning data and the inspection image data may be set such that the center or the center of gravity of the one solder fillet image matches the center of the first image frame and such that an electronic component-side region in the one solder fillet image is directed in a predetermined direction.

The technical features with regard to above Aspect 4 may be applied to above Aspect 3. More specifically, the second learning data may be set such that the center or the center of gravity of the one solder fillet image matches the center of the second image frame and such that the electronic component-side region in the one solder fillet image is directed in the predetermined direction. The inspection image data described in above Aspect 3 may be set in a similar manner.

The configuration of above Aspect 4 causes the direction and the position of each solder fillet to be substantially adjusted in the first learning data and in the inspection image data. This configuration enables detecting the defectiveness/non-defectiveness of the solder fillet with high accuracy, even when a relatively small number of the first learning data are used for generation of the first AI model. This configuration accordingly achieves the high inspection accuracy, while more effectively reducing the labor and the time for obtaining the first AI model.

Aspect 5. In the solder fillet inspecting device described in above Aspect 1, the control device may make the comparison between the inspection image data and the reconfiguration image data with only the one solder fillet image in the inspection image data as a comparison object.

In the solder fillet inspecting device of above Aspect 5, the control device makes a comparison between the inspection image data and the reconfiguration image data with only the one solder fillet image in the inspection image data as the comparison object. In other words, the control device excludes part other than the one solder fillet image in the inspection image data from the comparison object in the process of making a comparison between these two image data. This reduces the processing load in relation to the comparison between these two image data, compared with a configuration of making a comparison between the entirety of the inspection image data and the entirety of reconfiguration image data. This configuration accordingly increases the speed and the efficiency of the inspection. Furthermore, this configuration more reliably prevents the part other than the one solder fillet image in the inspection image data, i.e., a part having no relation to the solder fillet, from affecting the defectiveness/non-defectiveness detection and thereby further enhances the inspection accuracy.

Aspect 6. There is provided a solder fillet inspecting method for inspecting a solder fillet used to solder an electronic component to a printed circuit board. The solder fillet inspecting method comprises: an image data capturing process of capturing image data of an inspection target area in the printed circuit board that includes a solder fillet formed to solder an electronic component to the printed circuit board; an inspection image data obtaining process of obtaining, as an inspection object, inspection image data that includes an image of the solder fillet based on the image data captured in the image data capturing process; a reconfiguration image data obtaining process of obtaining reconfiguration image data by inputting the inspection image data into a first Artificial Intelligence (AI) model, wherein the first AI model is generated by learning of a neural network using only image data of a non-defective solder fillet as first learning data, and the neural network comprises an encoder configured to extract a feature quantity from input image data and a decoder configured to reconfigure the input image data from the feature quantity; a comparison process of making a comparison between the inspection image data and the reconfiguration image data; and a detection process of detecting defectiveness/non-defectiveness of the solder fillet based on a comparison result. The first learning data is generated by placing one solder fillet image that indicates a solder fillet corresponding to one land, in a first image frame having a larger size than a size of the one solder fillet image. The inspection image data obtaining process obtains the inspection image data that has a size identical with a size of the first learning data and that is generated by placing the one solder fillet image extracted from the image data captured in the image data capturing process, in an image frame having a size identical with the size of the first image frame for the first learning data.

The configuration of above Aspect 6 has similar functions and advantageous effects to those of Aspect 1 described above.

The technical features described above in the respective aspects may be combined appropriately. For example, the technical features with regard to above Aspect 3 or the like may be combined with the technical features with regard to above Aspect 2. In another example, at least one of the technical features with regard to above Aspects 2 to 5 may be applied to above Aspect 6.

### BRIEF DESCRIPTION OF DRAWINGS

FIG. 1 is a plan view illustrating partial closeup of a printed circuit board;

FIG. 2 is a block diagram illustrating the configuration of a production line of the printed circuit board;

FIG. 3 is a schematic configuration diagram schematically illustrating a solder fillet inspecting device;

FIG. 4 is a block diagram illustrating the functional configuration of the solder fillet inspecting device;

FIG. 5 is a schematic diagram illustrating the structure of a neural network;

FIG. 6 is a flowchart showing the flow of a learning process of the neural network;

FIG. 7 is a flowchart showing the flow of an inspection process;

FIG. 8 is a schematic diagram illustrating original image data for learning;

FIG. 9 is a schematic diagram illustrating areas occupied by solder fillets in the original image data for learning;

FIG. 10 is a schematic diagram illustrating one solder fillet image extracted from the original image data for learning;

FIG. 11 is a schematic diagram illustrating a first image frame and first learning data Ga;

FIG. 12 is a schematic diagram illustrating a first image frame and first learning data Gb;

FIG. 13 is a schematic diagram illustrating a second image frame and second learning data Gc;

FIG. 14 is a schematic diagram illustrating a second image frame and second learning data Gd;

FIG. 15 is a schematic diagram illustrating one example of original image data for inspection;

FIG. 16 is a schematic diagram illustrating areas occupied by solder fillets in the original image data for inspection;

FIG. 17 is a schematic diagram illustrating one example of one solder fillet image extracted from the original image data for inspection;

FIG. 18 is a schematic diagram illustrating one example of one solder fillet image extracted from the original image data for inspection;

FIG. 19 is a schematic diagram illustrating one example of first inspection image data Ka and a first image frame;

FIG. 20 is a schematic diagram illustrating one example of the first inspection image data Ka and the first image frame;

FIG. 21 is a schematic diagram illustrating one example of first inspection image data Kb and the first image frame;

FIG. 22 is a schematic diagram illustrating one example of second inspection image data Kc and a second image frame;

FIG. 23 is a schematic diagram illustrating one example of the second inspection image data Kc and the second image frame;

FIG. 24 is a schematic diagram illustrating one example of second inspection image data Kd and the second image frame;

FIG. 25 is a schematic diagram illustrating reconfiguration image data output from a first AI model when the first inspection image data Ka is input into the first AI model;

FIG. 26 is a schematic diagram illustrating reconfiguration image data output from a second AI model when the second inspection image data Kc is input into the second AI model;

FIG. 27 is a schematic diagram illustrating a solder fillet in a state of being protruded from a land; and

FIG. 28 is a schematic diagram illustrating one solder fillet image with regard to the solder fillet in the state of being protruded from the land.

### DETAILED DESCRIPTION OF EMBODIMENTS

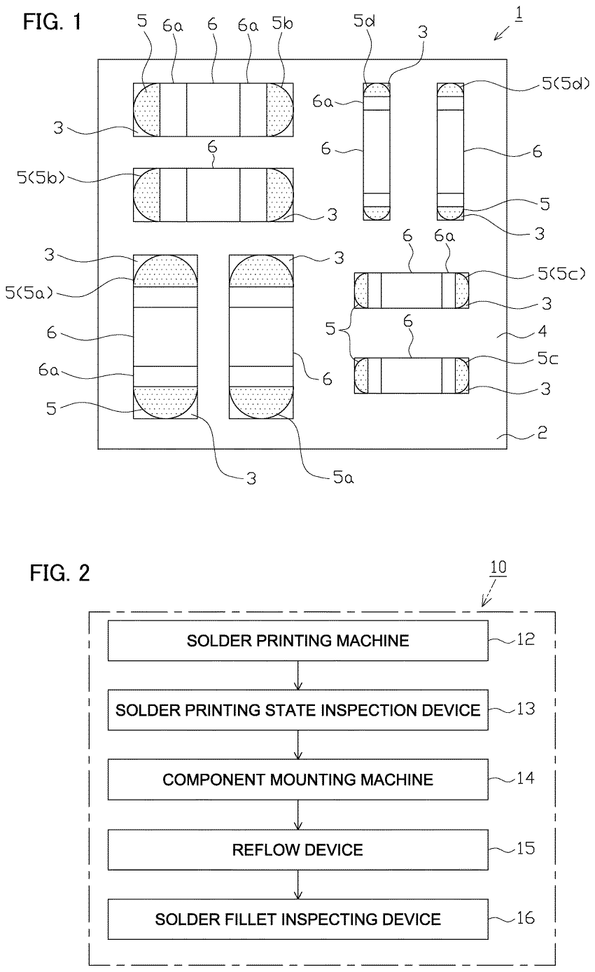

The following describes embodiments with reference to drawings. The configuration of a printed circuit board is described first. FIG. 1 is a plan view illustrating partial closeup of a printed circuit board.

As shown in FIG. 1, a printed circuit board 1 is configured by forming a wiring pattern (not shown) and a plurality of lands 3 made of copper foil on a surface of a plate-like base substrate 2 made of, for example, a glass epoxy resin. Part of the surface of the base substrate 2 other than the lands 3 is coated with a resist film 4.

Electronic components 6, such as chips, are mounted on the lands 3 via solder fillets 5. In FIG. 1 and other drawings, as a matter of convenience, portions representing the solder fillets 5 are shown in a dotted pattern. The solder fillets 5 are formed by heating solder paste, which is obtained by kneading solder particles with flux, in a reflow process described later. The solder fillets 5 are used to solder the electronic components 6 to the printed circuit board 1 and to join electrodes 6a with the lands 3. According to one or more embodiments, the solder fillets 5 include relatively large solder fillets 5a and 5b that are provided on relatively large lands 3 corresponding to relatively large electronic components 6, and relatively small solder fillets 5c and 5d that are provided on relatively small lands 3 corresponding to relatively small electronic components 6.

A production line (production process) of manufacturing the printed circuit board 1 is described next with reference to FIG. 2. FIG. 2 is a block diagram illustrating the configuration of a production line 10 of the printed circuit board 1. As shown in FIG. 2, the production line 10 includes a solder printing machine 12, a solder printing state inspection device 13, a component mounting machine 14, a reflow device 15, and a solder fillet inspecting device 16, which are located sequentially from an upstream side thereof (from an upper side in FIG. 2).

The solder printing machine 12 is configured to perform a solder printing process for printing solder paste on the respective lands 3 of the printed circuit board 1. The solder printing process prints the solder paste by, for example, screen printing. A procedure of screen printing first supplies the solder paste onto an upper face of a screen mask in the state that a lower face of the screen mask is in contact with the printed circuit board 1. The screen mask has a plurality of openings that are formed corresponding to the respective lands 3 of the printed circuit board 1. The procedure subsequently moves a predetermined squeegee, while bringing the predetermined squeegee into contact with the upper face of the screen mask, so as to fill the solder paste into the openings. The procedure then separates the printed circuit board 1 from the lower face of the screen mask. This causes the solder paste to be printed on the respective lands 3 of the printed circuit board 1.

The solder printing state inspection device 13 is configured to perform an inspection for the shape of the solder paste printed on each of the lands 3 and for the presence or the absence of any foreign substance adhering to the solder paste.

The component mounting machine 14 is configured to mount electronic components 6 on the lands 3 with the solder paste printed thereon. The electrodes 6a of each electronic component 6 are temporarily fastened to predetermined pieces of solder paste by the component mounting machine 14.

The reflow device 15 is configured to perform a reflow process that heats and melts the solder paste and thereby causes the electrodes 6a of the electronic components 6 to be solder joined with (soldered to) the respective lands 3. The reflow process forms the solder fillets 5 by heating the solder paste. As a result, this causes the electronic components 6 (the electrodes 6a) to be fixed to the respective lands 3.

The solder fillet inspecting device 16 is configured to perform an inspection for the shape, the area, the amount, and the like of each solder fillet 5 and thereby determine, for example, whether solder joint (soldering) is adequately performed in the reflow process. The solder fillet inspecting device 16 will be described later more in detail.

The production line 10 additionally includes conveyors or the like provided between the respective devices described above, for example, between the solder printing machine 12 and the solder printing state inspection device 13, and configured to transfer the printed circuit board 1, although not being specifically illustrated. The production line 10 also includes branching units provided between the solder printing state inspection device 13 and the component mounting machine 14 and on a downstream side of the solder fillet inspecting device 16. The printed circuit board 1 that is determined to be non-defective by the solder printing state inspection device 13 and by the solder fillet inspecting device 16 is guided directly to a downstream side, whereas the printed circuit board 1 that is determined to be defective by either the solder printing state inspection device 13 or the solder fillet inspecting device 16 is discharged by the branching unit to a defective storage unit.

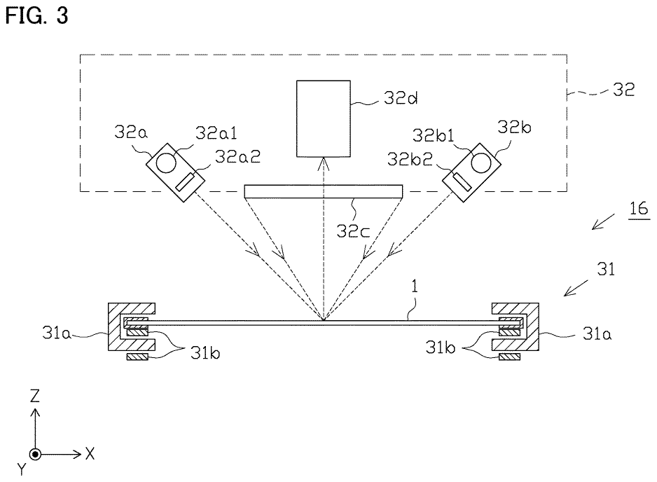

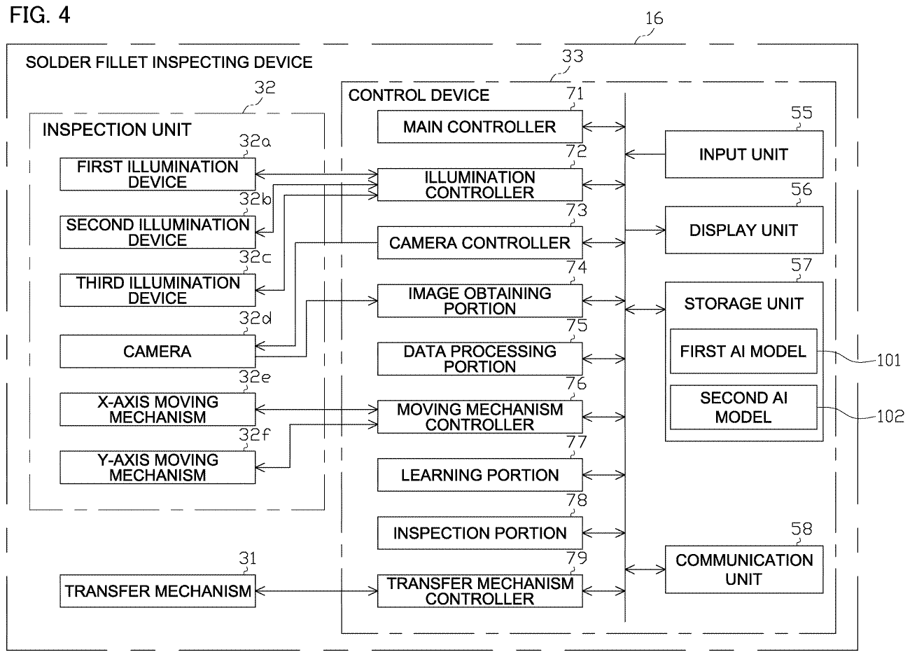

The following describes the configuration of the solder fillet inspecting device 16 in detail with reference to FIG. 3 and FIG. 4. FIG. 3 is a schematic configuration diagram schematically illustrating the solder fillet inspecting device 16. FIG. 4 is a block diagram illustrating the functional configuration of the solder fillet inspecting device 16.

The solder fillet inspecting device 16 includes a transfer mechanism 31 configured to perform transfer, positioning and the like of the printed circuit board 1; an inspection unit 32 configured to capture image data of the printed circuit board 1; and a control device 33 (shown in FIG. 4) configured to drive and control the transfer mechanism 31 and the inspection unit 32 and to perform various controls, image processing and arithmetic processing in the solder fillet inspecting device 16.

The transfer mechanism 31 includes a pair of transfer rails 31a placed along a carry in/out direction of the printed circuit board 1; and an endless conveyor belt 31b arranged such as to be rotatable relative to the respective transfer rails 31a. The transfer mechanism 31 is also provided with a drive unit or driver, such as a motor, configured to drive the conveyor belt 31b and a chuck mechanism configured to position the printed circuit board 1 at a predetermined position, although these components are not specifically illustrated. The transfer mechanism 31 is driven and controlled by the control device 33 (more specifically, by a transfer mechanism controller 79 thereof described later).

Under the configuration described above, when the printed circuit board 1 is carried into the solder fillet inspecting device 16, respective side edge portions of the printed circuit board 1 in a width direction that is perpendicular to the carry in/out direction, are inserted into the respective transfer rails 31a, and the printed circuit board 1 is placed on the conveyor belt 31b. The conveyor belt 31b subsequently starts operation to transfer the printed circuit board 1 to a predetermined inspection position. When the printed circuit board 1 reaches the inspection position, the conveyor belt 31b stops and the chuck mechanism is actuated. Such actuation of the chuck mechanism presses up the conveyor belt 31b and causes the respective side edge portions of the printed circuit board 1 to be placed between the conveyor belt 31b and respective upper sides of the transfer rails 31a. This positions and fixes the printed circuit board 1 at the inspection position. On completion of the inspection, the fixation by the chuck mechanism is released and the conveyor belt 31b starts operation. The printed circuit board 1 is accordingly carried out from the solder fillet inspecting device 16. The configuration of the transfer mechanism 31 is naturally not limited to the configuration of the embodiments described above, but another configuration may be employable.

The inspection unit 32 is placed above the transfer rails 31a (above the transfer path of the printed circuit board 1). The inspection unit 32 is provided with a first illumination device (or first illuminator) 32a, a second illumination device (or second illuminator) 32b, a third illumination device (or third illuminator) 32c, and a camera 32d. According to one or more embodiments, the camera 32d configures the “image data capturing unit” or “imaging device”.

The inspection unit 32 is also provided with an X-axis moving mechanism 32e (shown in FIG. 4) configured to allow for a movement in an X-axis direction (a left-right direction of FIG. 3) and a Y-axis moving mechanism 32f (shown in FIG. 4) configured to allow for a movement in a Y-axis direction (a front-back direction of FIG. 3). Both the moving mechanisms 32e and 32f may comprise rails and/or motors, and are driven and controlled by the control device 33 (more specifically, by a moving mechanism controller 76 thereof described later).

Each of the first illumination device 32a and the second illumination device 32b irradiates a predetermined inspection target area of the printed circuit board 1 with a predetermined light for three-dimensional measurement (patterned light having a striped light intensity distribution) obliquely downward in a process of three-dimensional measurement of the printed circuit board 1.

More specifically, the first illumination device 32a includes a first light source 32al configured to emit a predetermined light and a first liquid crystal shutter 32a2 configured to form a first lattice that converts the light emitted from the first light source 32al into a first patterned light having a striped light intensity distribution. The first illumination device 32a is driven and controlled by the control device 33 (more specifically, by an illumination controller 72 thereof described later).

The second illumination device 32b includes a second light source 32b1 configured to emit a predetermined light and a second liquid crystal shutter 32b2 configured to form a second lattice that converts the light emitted from the second light source 32b1 into a second patterned light having a striped light intensity distribution. The second illumination device 32b is driven and controlled by the control device 33 (more specifically, by the illumination controller 72 thereof described later).

Under the configuration described above, the light emitted from each of the light sources 32al and 32b1 is guided to a condenser lens (not shown) to be output as parallel light beams and is then guided to a projector lens (not shown) via the corresponding liquid crystal shutter 32a2 or 32b2 to be projected as a patterned light on the printed circuit board 1. According to one or more embodiments, switching control of the liquid crystal shutters 32a2 and 32b2 is performed, such as to shift the phase of each patterned light by every ¼ pitch.

Using the liquid crystal shutters 32a2 and 32b2 as the lattices allows for radiation of the patterned lights close to an ideal sine wave. This configuration enhances the measurement resolution of three-dimensional measurement. This configuration also enables the phase shift control of the patterned light to be performed electrically and thereby allows for size reduction of the device.

The third illumination device 32c is configured to irradiate a predetermined inspection target area of the printed circuit board 1 with a predetermined light for two-dimensional measurement (for example, uniform light) in a process of two-dimensional measurement of the printed circuit board 1. The third illumination device 32c is provided with a ring light configured to radiate blue light, a ring light configured to radiate green light, and a ring light configured to radiate red light. The third illumination device 32c has a configuration similar to the configuration of a known art, so that detailed explanation of this third illumination device 32c is omitted.

The camera 32d is configured to take an image of a predetermined inspection target area of the printed circuit board 1 from directly above the area. The camera 32d includes an imaging element, such as a CCD (Charge Coupled Device)-type image sensor or a CMOS (Complementary Metal Oxide Semiconductor)-type image sensor and an optical system (for example, a lens unit and a diaphragm) configured to form an image of the printed circuit board 1 on the imaging element. The camera 32d is placed such that an optical axis thereof is extended along a vertical direction (Z-axis direction). The imaging element is, however, not limited to these examples, but another imaging element may be employed.

The camera 32d is driven and controlled by the control device 33 (more specifically, by a camera controller 73 thereof described later). More specifically, the control device 33 causes the camera 32d to perform an imaging process, in synchronism with an irradiation process performed by the respective illumination devices 32a, 32b, 32c. This configuration causes the camera 32d to take an image of the light reflected from the printed circuit board 1 out of the lights radiated from one of the illumination devices 32a, 32b and 32c. As a result, the camera 32d captures image data of the inspection target area of the printed circuit board 1 that includes a solder fillet 5. The “inspection target area” of the printed circuit board 1 denotes one area out of a plurality of areas that are set in advance in the printed circuit board 1 with setting the size of an imaging visual field (imaging range) of the camera 32d as one unit.

Furthermore, the camera 32d according to one or more embodiments is configured by a color camera. This configuration enables the camera 32d to simultaneously take images of the lights of the respective colors that are radiated concurrently from the respective color ring lights of the third illumination device 32c and reflected from the printed circuit board 1.

Image data taken and generated by the camera 32d is converted into a digital signal inside of the camera 32d and is subsequently transferred in the form of the digital signal to the control device 33 (more specifically, to an image obtaining portion 74 thereof described later). The control device 33 then stores the transferred image data and performs a variety of image processing operations, arithmetic operations and the like, based on the image data.

The control device 33 is configured by a computer including a CPU (Central Processing Unit) which executes predetermined arithmetic operations, a ROM (Read Only Memory) which stores a variety of programs, fixed value data and the like, a RAM (Random Access Memory) where a variety of data are temporarily stored in the course of execution of various arithmetic operations, and peripheral circuits thereof.

The CPU operates according to the various programs, so that the control device 33 serves as various functional portions, such as a main controller 71, an illumination controller 72, a camera controller 73, an image obtaining portion 74, a data processing portion 75, a moving mechanism controller 76, a learning portion 77, an inspection portion 78, and a transfer mechanism controller 79.

The respective functional portions described above are implemented by cooperation of various hardware components, such as the CPU, the ROM and the RAM, described above. There is no need to clearly distinguish the functions implemented by the hardware configuration from the functions implemented by the software configuration. Part or the entirety of these functions may be implemented by a hardware circuit, such as an IC.

The control device 33 is further provided with, for example, an input unit (or input device) 55 that is configured by a keyboard and a mouse, a touch panel or the like; a display unit (or display device) 56 that is configured by a liquid crystal display or the like and that is provided with a display screen; a storage unit (or storage) 57 that is configured to store a variety of data, programs, results of arithmetic operations, results of inspections and the like; and a communication unit 58 that is configured to send and receive various data to and from outside.

The following describes the details of the above respective functional portions of the control device 33.

The main controller 71 is a functional portion of controlling the entirety of the solder fillet inspecting device 16. The main controller 71 is configured to send and receive a variety of signals to and from the other functional portions including the illumination controller 72 and the camera controller 73.

The illumination controller 72 is a functional portion of driving and controlling the illumination devices 32a, 32b, and 32c. The illumination controller 72 is configured to perform, for example, switching control of the irradiation lights, based on a command signal from the main controller 71.

The camera controller 73 is a functional portion of driving and controlling the camera 32d. The camera controller 73 is configured to control, for example, an imaging timing, based on a command signal from the main controller 71.

The image obtaining portion 74 is a functional portion of importing the image data taken and obtained by the camera 32d.

The data processing portion 75 is a functional portion of performing predetermined image processing for the image data imported by the image obtaining portion 74 and of using the image data to perform a two-dimensional measurement process and a three-dimensional measurement process.

The moving mechanism controller 76 is a functional portion of driving and controlling the X-axis moving mechanism 32e and the Y-axis moving mechanism 32f. The moving mechanism controller 76 is configured to control the position of the inspection unit 32, based on a command signal from the main controller 71. The moving mechanism controller 76 drives and controls the X-axis moving mechanism 32e and the Y-axis moving mechanism 32f, such as to move the inspection unit 32 to a position above an arbitrary inspection target area of the printed circuit board 1, which is positioned and fixed at the inspection position. The inspection unit 32 is sequentially moved to a plurality of inspection target areas set on the printed circuit board 1 and sequentially performs an inspection with regard to each of the inspection target areas. This configuration accordingly performs an inspection for the entire area of the printed circuit board 1.

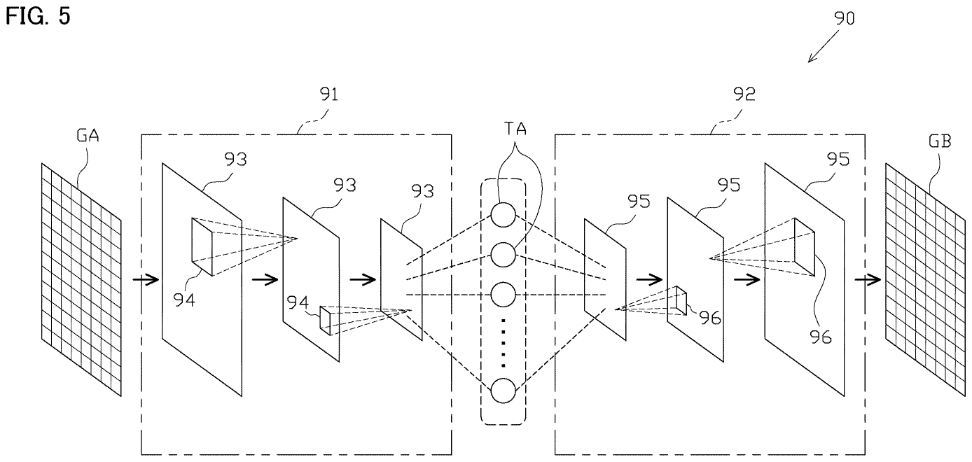

The learning portion 77 is a functional portion of using learning data to perform learning of a deep neural network 90 (hereinafter simply referred to as “neural network 90”: as shown in FIG. 5) and of constructing a first Artificial Intelligence (AI) model 101 serving as the “identification unit” and a second AI model 102 serving as the “second identification unit”.

Each of the AI models 101 and 102 according to one or more embodiments is a generation model constructed by deep learning of the neural network 90 with using only image data of a non-defective solder fillet 5, as the learning data, as described later, and has a so-called autoencoder structure.

The structure of the neural network 90 is described with reference to FIG. 5. FIG. 5 is a schematic diagram conceptually illustrating the structure of the neural network 90. As shown in FIG. 5, the neural network 90 has the structure of a convolutional autoencoder (CAE) that includes an encoder portion 91 serving as an “encoding unit” or “encoder” configured to extract a feature quantity (latent variable) TA from input image data GA; and a decoder portion 92 serving as a “decoding unit” or “decoder” configured to reconstruct image data GB from the feature quantity TA.

The structure of the convolutional autoencoder is publicly known, so that the detailed description thereof is omitted. The encoder portion 91 has a plurality of convolution layers 93. Each of the convolution layers 93 is configured to output the results of convolution operations of input data by using a plurality of filters (kernels) 94, as input data for a subsequent layer. Similarly, the decoder portion 92 has a plurality of deconvolution layers 95. Each of the deconvolution layers 95 is configured to output the results of deconvolution operations of input data by using a plurality of filters (kernels) 96, as input data of a subsequent layer. The learning process described later updates weights (parameters) of the respective filters 94 and 96.

The inspection portion 78 is a functional portion of performing an inspection for the solder fillets 5. According to one or more embodiments, the inspection portion 78 is configured to perform an inspection and determine whether the solder fillets 5 are formed adequately in terms of the shape, the area, and the amount.

The transfer mechanism controller 79 is a functional portion of driving and controlling the transfer mechanism 31. The transfer mechanism controller 79 is configured to control the position of the printed circuit board 1, based on a command signal from the main controller 71.

The storage unit 57 is configured by, for example, an HDD (Hard Disk Drive), an SSD (Solid State Drive) or the like and has a predetermined storage area for storing, for example, the respective AI models 101 and 102 (the neural network 90 and learning information obtained by learning of the neural network 90).

The communication unit 58 is provided with, for example, a wireless communication interface in conformity with a communications standard, such as a wired LAN (Local Area Network) and a wireless LAN and is configured to send and receive various data to and from the outside. For example, results of an inspection performed by the inspection portion 78 are output to the outside via the communication unit 58. Results of an inspection performed by the solder printing state inspection device 13 are input via the communication unit 58.

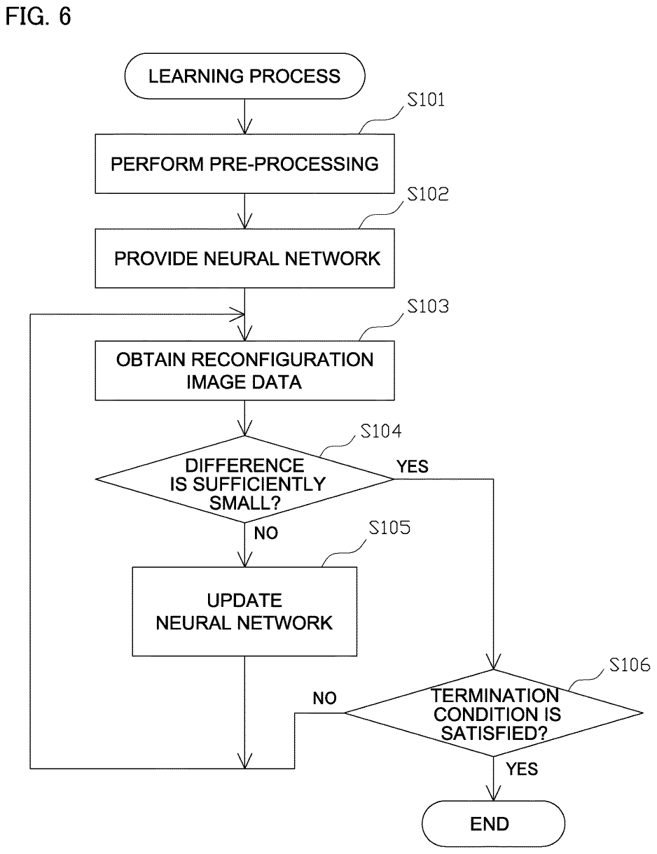

The following describes a learning process of the neural network 90 performed by the solder fillet inspecting device 16, with reference to the flowchart of FIG. 6.

When the learning process is started by execution of a predetermined learning program, the main controller 71 first performs preprocessing for learning of the neural network 90 at step S101.

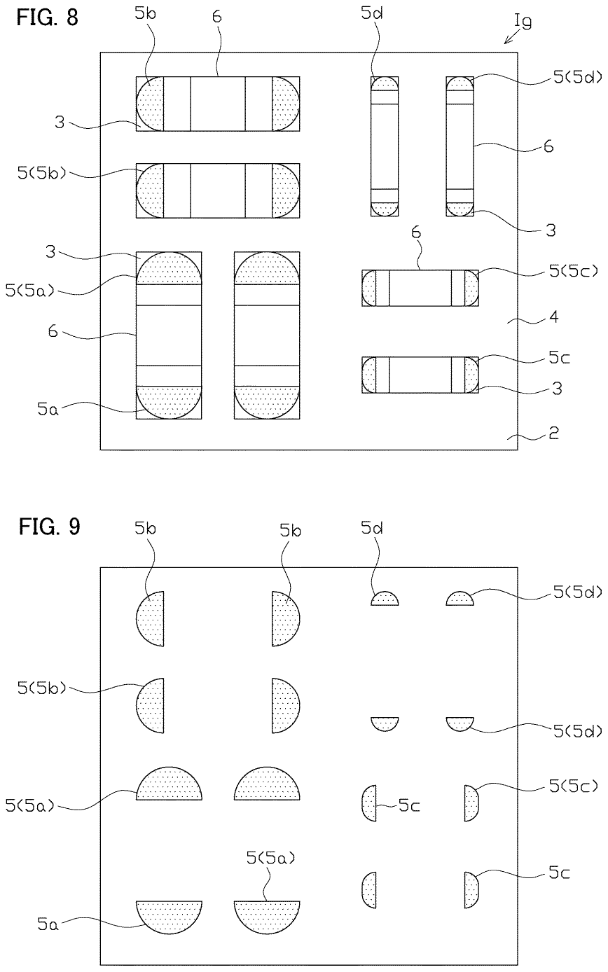

In this pre-processing, the main controller 71 obtains inspection information with regard to a large number of printed circuit boards 1 accumulated in the solder fillet inspecting device 16. The main controller 71 subsequently obtains original image data for learning Ig (as shown in, for example, FIG. 8), which is image data with regard to the non-defective solder fillet 5 that has passed a post-reflow inspection, from the storage unit 57, based on the obtained inspection information.

This original image data for learning Ig is image data with regard to the printed circuit board 1 after a reflow process and is used in order to obtain learning data Ga, Gb, Gc, and Gd described later (hereinafter may be simply referred to as “learning data Ga to Gd), which are used for learning of the neural network 90. This original image data for learning Ig include three-dimensional data, which is image data captured by the camera 32d that takes an image of the printed circuit board 1 in the state that the printed circuit board 1 is irradiated with the patterned light from the first illumination device 32a or from the second illumination device 32b; and two-dimensional data, which is image data captured by the camera 32d that takes an image of the printed circuit board 1 in the state that the printed circuit board 1 is irradiated with the uniform light from the third illumination device 32c.

The original image data for learning Ig may be unprocessed image data without performing any specific process for the image data captured by the camera 32d (for example, monochromatic luminance image data or RGB luminance image data) or may be processed image data with performing a predetermined process for the image data captured by the camera 32d (for example, HLS image data obtained by conversion of RGB image data or height image data obtained by conversion of image data). Furthermore, the original image data for learning Ig may be image data obtained in the case of employing a so-called color highlight system (i.e., in the case of employing a method of irradiating the surface of a solder fillet 5 with red, green and blue lights at different angles of incidence and causing the camera 32d to take images of reflected lights of the respective colors, so as to detect a three-dimensional shape of the solder fillet 5 as two-dimensional hue information).

In the pre-processing, the main controller 71 subsequently generates first learning data Ga and Gb and second learning data Gc and Gd (refer to FIG. 11 to FIG. 14 for the learning data Ga to Gd). According to one or more embodiments, the first learning data Ga and Gb correspond to the “learning data”. The first learning data Ga and Gb are used for generation of the first AI model 101. The second learning data Gc and Gd are used for generation of the second AI model 102.

In order to obtain the respective learning data Ga to Gd, the main controller 71 first specifies areas occupied by the solder fillets 5 in the obtained original image data for learning Ig (as shown in, for example, FIG. 9). When the original image data for learning Ig is two-dimensional data, the main controller 71 uses, for example, the luminance, the hue, and the saturation to specify the areas occupied by the solder fillets 5. When the original image data for learning is three-dimensional data, the main controller 71 uses, for example, the height information to specify the areas occupied by the solder fillets 5.

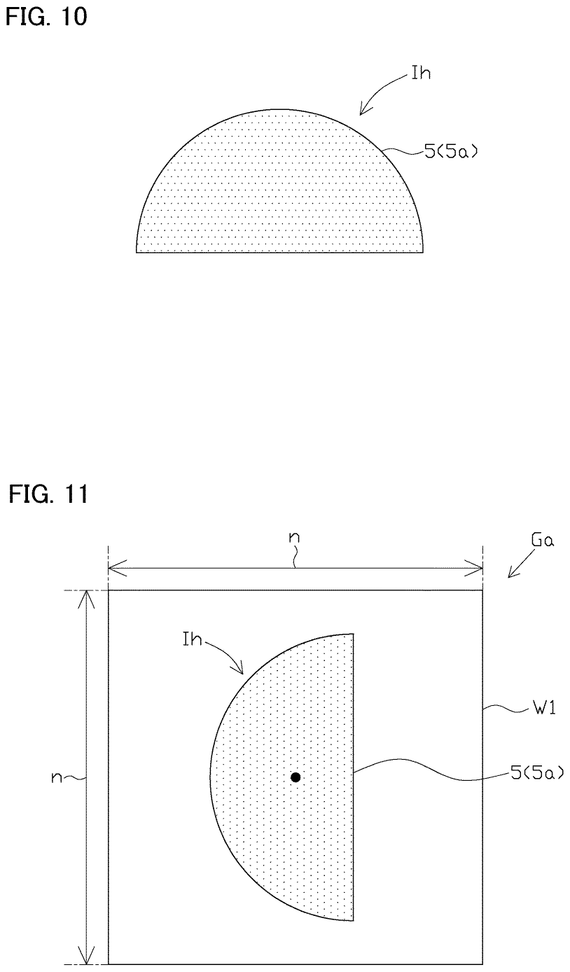

The main controller 71 subsequently extracts an image of a linkage component (block portion) in each specified area occupied by a solder fillet 5, as one solder fillet image Ih (as shown in, for example, FIG. 10). One solder fillet image Ih corresponds to one land 3. According to one or more embodiments, in the area occupied by a solder fillet 5, a linkage component (block portion) located on one land 3 in design is extracted as one solder fillet image Ih. According to a modification, however, one linkage component (block portion) may simply be extracted as one solder fillet image Ih without taking into account the position of the land 3.

The main controller 71 then selects an image frame where the extracted one solder fillet image Ih is to be pasted, out of a first image frame W1 and a second image frame W2 (refer to FIG. 11 to FIG. 14 for the respective image frames W1 and W2).

According to one or more embodiments, the first image frame W1 is a rectangular image having a height (a width in a vertical direction of the sheet surface of, for example, FIG. 11) of n (pixels) and a width (a width in a left to right direction of the sheet surface of, for example, FIG. 11) of n (pixels). The size (the width and the height) of the first image frame W1 is set to be larger than the size of the extracted one solder fillet image Ih, based on design data or the like.

The second image frame W2 is a rectangular image having a height of m (pixels) and a width of m (pixels). The size (the width and the height) of the second image frame W2 is set to be smaller than the size of the first image frame W1.

In the respective image frames W1 and W2 (in the case where no image is pasted), all pixels are set to have identical values. For example, the luminance value and the height information of all the respective pixels configuring the respective image frames W1 and W2 are set to be “0”. This identical value may be relatively significantly different from the values of pixels configuring one solder fillet image Ih. Thus a value (for example, a negative number) other than generally used values may be used as this identical value.

Selection out of the image frames W1 and W2 is performed, based on the size and the shape of the one solder fillet image Ih. In the case where the size (the width and the height) of the one solder fillet image Ih is larger than the size of the second image frame W2, the first image frame W1 is selected. In the case where the size of the one solder fillet image Ih is smaller than the size of the second image frame W2, on the other hand, the second image frame W2 is selected.

The main controller 71 then pastes the one solder fillet image Ih to the selected one of the image frames W1 and W2 and thereby obtains one of the learning data Ga to Gd by providing the one solder fillet image Ih in the selected one of the image frames W1 and W2.

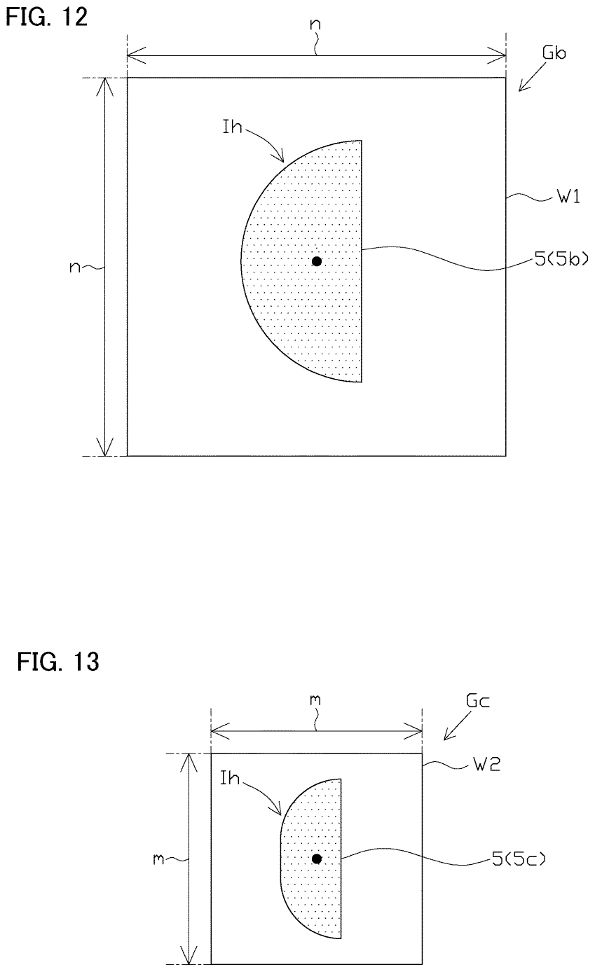

According to one or more embodiments, the first learning data Ga (refer to, for example, FIG. 11) is obtained by pasting the one solder fillet image Ih corresponding to a solder fillet 5a to the first image frame W1. The first learning data Gb (refer to, for example, FIG. 12) is obtained by pasting the one solder fillet image Ih corresponding to a solder fillet 5b to the first image frame W1.

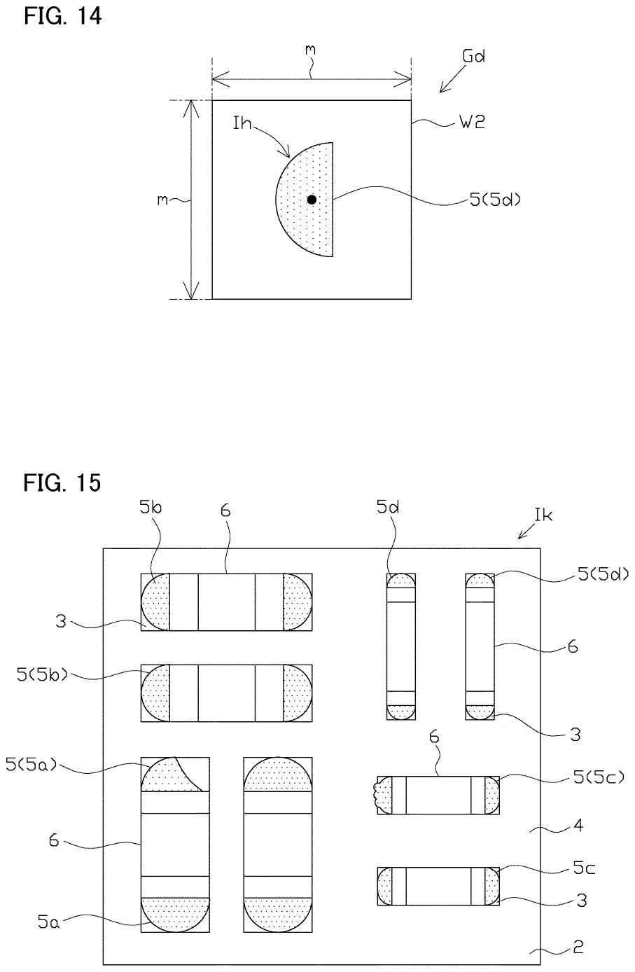

Furthermore, the second learning data Gc (refer to, for example, FIG. 13) is obtained by pasting the one solder fillet image Ih corresponding to a solder fillet 5c to the second image frame W2. The second learning data Gd (refer to, for example, FIG. 14) is obtained by pasting the one solder fillet image Ih corresponding to a solder fillet 5d to the second image frame W2.

An adjustment of the pasting position and a rotating operation of the one solder fillet image Ih are performed to set each of the learning data Ga to Gd, such that the center or the center of gravity of the one solder fillet image Ih matches the center of the image frame W1 or W2 and such that an electronic component 6-side region in the one solder fillet image Ih is directed in a predetermined direction. Herein the “electronic component 6-side region in the one solder fillet image Ih” denotes a region adjacent to the electronic component 6 in the one solder fillet image Ih and is a linear region according to one or more embodiments. The rotating operation of the one solder fillet image Ih is performed, such that this linear region is directed in a predetermined direction (for example, a rightward direction).

Repeating the above series of processing to extract one solder fillet image Ih and to paste the extracted one solder fillet image Ih to the selected one of the image frames W1 and W2 enables the respective learning data Ga to Gd to be obtained from one original image data for learning Ig. Furthermore, using a plurality of original image data for learning Ig enables required numbers of the first learning data Ga and Gb and required numbers of the second learning data Gc and Gd to be obtained eventually. According to one or more embodiments, each of the learning data Ga to Gd includes learning data obtained based on the two-dimensional data and learning data obtained based on the three-dimensional data.

After the main controller 71 obtains the required numbers of the learning data Ga to Gd required for learning at step S101, the learning portion 77 provides a neural network 90 that has not yet been learnt, based on a command from the main controller 71 at subsequent step S102. For example, the learning portion 77 reads out a neural network 90 that is stored in advance in the storage unit 57 or the like. In another example, the learning portion 77 constructs a neural network 90, based on network configuration information (for example, the number of layers of the neural network and the number of nodes in each layer) that is stored in the storage unit 57 or the like.

According to one or more embodiments, the learning portion 77 separately constructs a neural network for learning that uses the first learning data Ga and Gb and a neural network for learning that uses the second learning data Gc and Gd, as the neural networks 90. The learning portion 77 also separately constructs a neural network for learning that uses the learning data Ga to Gd obtained based on the two-dimensional data and a neural network for learning that uses the learning data Ga to Gd obtained based on the three-dimensional data, as the neural networks 90. The configuration of one or more embodiments accordingly constructs a total of four different neural networks 90.

At step S103, the learning portion 77 subsequently obtains reconfiguration image data. More specifically, based on a command from the main controller 71, the learning portion 77 gives the learning data Ga to Gd obtained at step S102 as input data to an input layer of the neural network 90 and obtains reconfiguration image data output from an output layer of the neural network 90. Furthermore specifically, the learning portion 77 gives learning data corresponding to the neural network 90 out of the learning data Ga to Gd obtained at step S102, as the input data to the input layer of the neural network 90 and obtains reconfiguration image data output from the output layer of the neural network 90. For example, the learning portion 77 gives the first learning data Ga and Gb obtained based on the two-dimensional data, as the input data to the input layer of the neural network 90 that performs learning by using the first learning data Ga and Gb, and obtains reconfiguration image data output from the neural network 90. In this manner, the learning portion 77 inputs adequate learning data among the learning data Ga to Gd to each of the total of four different neural networks 90 and obtains the output reconfiguration image data.

At subsequent step S104, the learning portion 77 makes a comparison between one of the input learning data Ga to Gd and the reconfiguration image data output from the neural network 90 and determines whether a difference between the input data and the output data is sufficiently small (whether the difference is equal to or less than a predetermined reference value).

When the difference is sufficiently small, the learning portion 77 subsequently determines whether a termination condition of learning is satisfied at step S106. It is determined that the termination condition is satisfied, for example, in the case where an affirmative answer is continually given a predetermined number of times at step S104 without proceeding to the processing of step S105 described later or in the case where the learning operation using all the provided learning data Ga to Gd is repeated a predetermined number of times. When the termination condition is satisfied, the learning portion 77 stores the neural networks 90 and the learning information thereof (updated parameters and the like described later), as the AI models 101 and 102, in the storage unit 57 and then terminates this learning process.

According to one or more embodiments, the learning portion 77 eventually stores an AI model generated by learning the first learning data Ga and Gb obtained based on the two-dimensional data and an AI model generated by learning the first learning data Ga and Gb obtained based on the three-dimensional data, as the first AI models 101.

Furthermore, the learning portion 77 stores an AI model generated by learning the second learning data Gc and Gd obtained based on the two-dimensional data and an AI model generated by learning the second learning data Gc and Gd obtained based on the three-dimensional data, as the second AI models 102.

When the termination condition is not satisfied at step S106, on the other hand, the learning portion 77 returns to step S103 to perform learning of the neural network 90 again.

When the difference is not sufficiently small at step S104, the learning portion 77 performs a network updating process (learning of the neural network 90) at step S105 and then goes back to step S103 to repeat the series of processing described above. More specifically, the network updating process at step S105 uses a known learning algorithm, for example, an error backpropagation method, and updates the weights (parameters) of the respective filters 94 and 96 described above in the neural network 90 to more appropriate values, such as to minimize a loss function that represents a difference between each of the learning data Ga to Gd and the reconfiguration image data. For example, BCE (Binary Cross-entropy) may be used as the loss function.

Repeating the processing of steps S103 to S105 a multiple number of times minimizes the difference between each of the learning data Ga to Gd and the reconfiguration image data in the neural network 90 and enables the more accurate reconfiguration image data to be output from the neural network 90.

In the case of input of image data of a non-defective solder fillet 5, each of the eventually obtained AI models 101 and 102 generates reconfiguration image data that is substantially identical with the input image data. In the case of input of image data with regard to a defective solder fillet 5 in terms of the shape, the area, or the amount of the solder fillet 5, each of the AI models 101 and 102 generates reconfiguration image data that is substantially identical with modified image data after modification of the shape, the area, or the amount of the solder fillet 5. In other words, in the case where the solder fillet 5 is defective, virtual image data with regard to the solder fillet 5 on the assumption of no defective portion is generated as the reconfiguration image data with regard to the solder fillet 5.

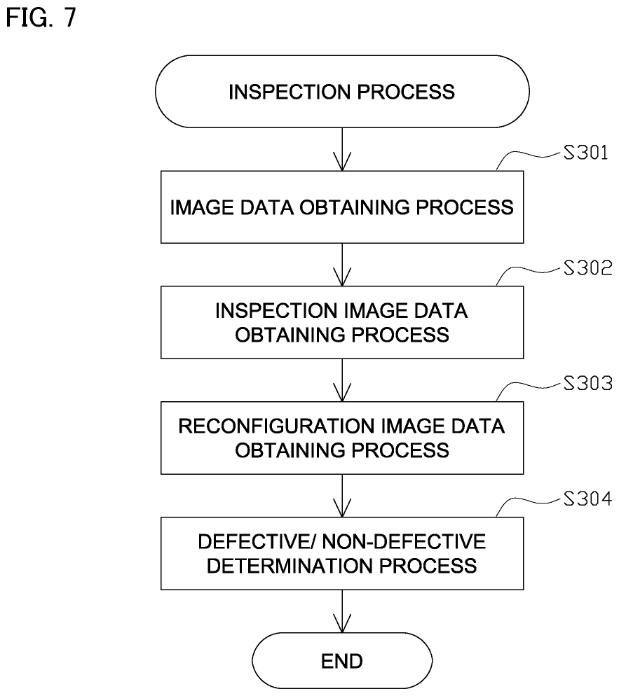

The following describes an inspection process performed by the solder fillet inspecting device 16 with reference to the flowchart of FIG. 7. The inspection process shown in FIG. 7 is performed for each of the inspection target areas in the printed circuit board 1.

When the printed circuit board 1 is carried into the solder fillet inspecting device 16 and is positioned at a predetermined inspection position, an inspection process is started by execution of a predetermined inspection program.

When the inspection process is started, an image data capturing process is performed first at step S301. The image data capturing process captures original image data for inspection Ik (refer to, for example, FIG. 15) with regard to the printed circuit board 1 as an inspection object. The original image data for inspection Ik is image data used to obtain inspection image data Ka, Kb, Kc, and Kd described later (hereinafter may be simply referred to as “inspection image data Ka to Kd”). Examples of the printed circuit board 1 as the inspection object described in one or more embodiments include a printed circuit board with a solder fillet 5 partly protruded from a land 3 and a printed circuit board with any abnormality in the shape or the area of a solder fillet 5.

The original image data for inspection Ik include three-dimensional data that is image data obtained by causing the camera 32d to take an image of the printed circuit board 1 in the state that the printed circuit board 1 is irradiated with the patterned light from either the first illumination device 32a or the second illumination device 32b; and two-dimensional data that is image data obtained by causing the camera 32d to take an image of the printed circuit board 1 in the state that the printed circuit board 1 is irradiated with the uniform light from the third illumination device 32c. The image data capturing process includes a process of capturing three-dimensional data and a process of capturing two-dimensional data.

The process of capturing three-dimensional data is described first. This process changes the phase of the first patterned light radiated from the first illumination device 32a and performs four imaging operations under the first patterned light having different phases. The process subsequently changes the phase of the second patterned light radiated from the second illumination device 32b and performs four imaging operations under the second patterned light having different phases. This process accordingly obtains a total of eight different three-dimensional data. This is described more in detail.

As described above, when the printed circuit board 1 carried into the solder fillet inspecting device 16 is positioned and fixed at a predetermined inspection position, in response to a command from the main controller 71, the moving mechanism controller 76 drives and controls the X-axis moving mechanism 32e and the Y-axis moving mechanism 32f such as to move the inspection unit 32 and to adjust the imaging visual field (imaging range) of the camera 32d to a predetermined inspection target area of the printed circuit board 1.

In the meantime, the illumination controller 72 performs switchover control of the liquid crystal shutters 32a2 and 32b2 of both the illumination devices 32a and 32b to set the positions of the first lattice and the second lattice formed by the respective liquid crystal shutters 32a2 and 32b2 to predetermined reference positions.

On completion of the switchover setting of the first lattice and the second lattice, the illumination controller 72 causes the first light source 32al of the first illumination device 32a to emit and radiate the first patterned light, and the camera controller 73 drives and controls the camera 32d to perform a first imaging process under the first patterned light. Image data generated by the imaging process is occasionally imported by the image obtaining portion 74 (the same applies hereinafter). This causes three-dimensional data of the inspection target area including a plurality of lands 3 (a plurality of solder fillets 5) to be obtained.

After that, the illumination controller 72 turns off the first light source 32al of the first illumination device 32a, simultaneously with termination of the first imaging process under the first patterned light, and performs a switchover control of the first liquid crystal shutter 32a2. More specifically, the illumination controller 72 performs switchover setting to change the position of the first lattice formed by the first liquid crystal shutter 32a2 from the reference position to a second position having the phase of the first patterned light shifted by one quarter pitch (90 degrees).

On completion of the switchover setting of the first lattice, the illumination controller 72 causes the light source 32al of the first illumination device 32a to emit and radiate the first patterned light, and the camera controller 73 drives and controls the camera 32d to perform a second imaging process under the first patterned light. The series of processing described above is then performed repeatedly, so that four different three-dimensional data are obtained under the first patterned light having the phase shifted by every 90 degrees.

The illumination controller 72 subsequently causes the second light source 32b1 of the second illumination device 32b to emit and radiate the second patterned light, and the camera controller 73 drives and controls the camera 32d to perform a first imaging process under the second patterned light.

After that, the illumination controller 72 turns off the second light source 32b1 of the second illumination device 32b, simultaneously with termination of the first imaging process under the second patterned light, and performs a switchover control of the second liquid crystal shutter 32b2. More specifically, the illumination controller 72 performs switchover setting to change the position of the second lattice formed by the second liquid crystal shutter 32b2 from the reference position to a second position having the phase of the second patterned light shifted by one quarter pitch (90 degrees).

On completion of the switchover setting of the second lattice, the illumination controller 72 causes the light source 32b1 of the second illumination device 32b to emit and radiate the second patterned light, and the camera controller 73 drives and controls the camera 32d to perform a second imaging process under the second patterned light. The series of processing described above is then performed repeatedly, so that four different three-dimensional data are obtained under the second patterned light having the phase shifted by every 90 degrees.

The process of capturing two-dimensional data is described next. In this process, in response to a command from the main controller 71, the illumination controller 72 causes the third illumination device 32c to emit and irradiate a predetermined inspection target area with uniform light, and the camera controller 73 drives and controls the camera 32d to perform an imaging process under the uniform light. This process takes an image of the predetermined inspection target area on the printed circuit board 1 and obtains two-dimensional data with regard to the inspection target area.

The original image data for inspection Ik (three-dimensional data and two-dimensional data) obtained are stored in the storage unit 57.

The original image data for inspection Ik may be image data in the original state taken by the camera 32d and without any specific processing (for example, monochromatic luminance image data or RGB luminance image data) or may be image data obtained by processing the image data taken by the camera 32d by a predetermined process (for example, HLS image data obtained by conversion of RGB image data and height data obtained by conversion of image data). Moreover, the original image data for inspection Ik may be image data obtained in the case where a so-called color highlight system is employed.

An inspection image data obtaining process is subsequently performed at step S302. The inspection image data obtaining process obtains first inspection image data Ka and Kb and second inspection image data Kc and Kd respectively described later, based on the original image data for inspection Ik captured by the image data capturing process.

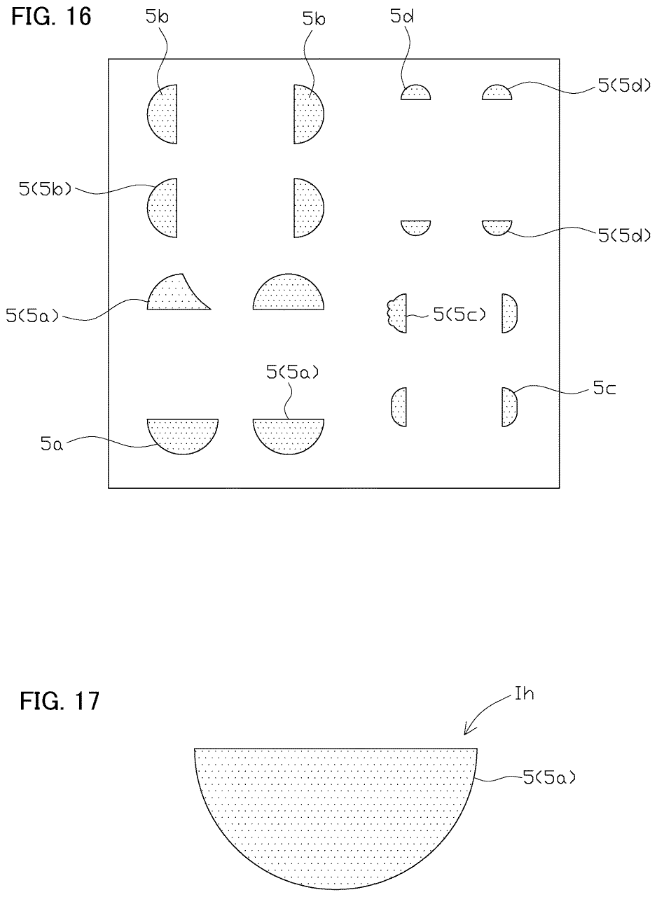

The process of obtaining these inspection image data Ka to Kd first specifies areas occupied by the solder fillets 5 in the obtained original image data for inspection Ik (as shown in, for example, FIG. 16). The areas occupied by the solder fillets 5 may be specified by using the luminance, the hue, the saturation, the height information and the like.

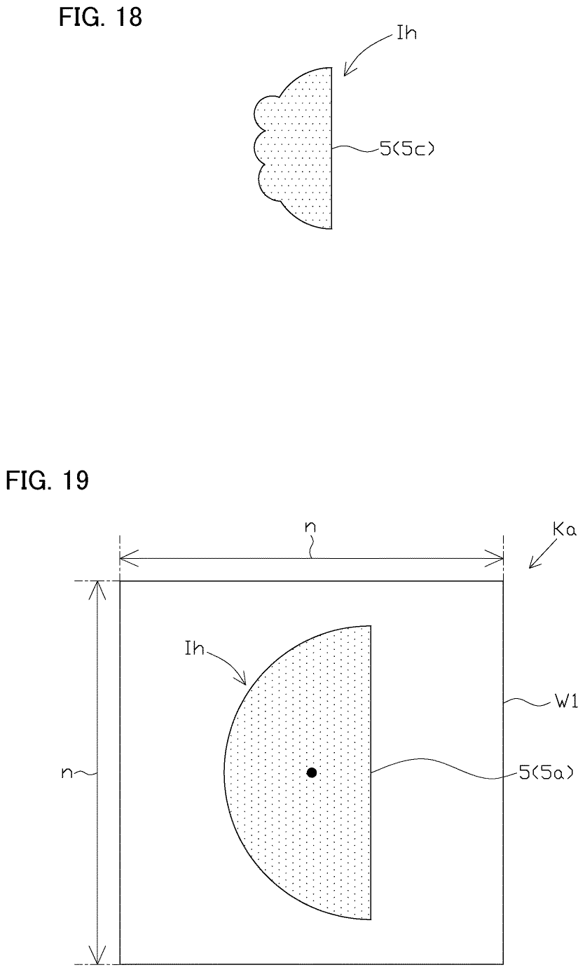

The process subsequently extracts one solder fillet image Ih in each specified area occupied by a solder fillet 5 (as shown in, for example, FIG. 17 and FIG. 18). One solder fillet image Ih corresponds to one land 3. According to one or more embodiments, an entire image which at least partly overlaps with one land 3 on the design data or on the production data, out of a linkage component (block portion) in the specified area, is extracted as one solder fillet image Ih. Accordingly, in the case where part of a linkage component is protruded from a land 3 on the design data or on the production data, one solder fillet image Ih is configured by the entirety of the linkage component including the part protruded from the land 3 (as shown in, for example, FIG. 18). A modification may not use the design data or the like but may simply extract one linkage component as one solder fillet image Ih. Moreover, the one solder fillet image Ih may include a land 3, an electrode 6a and the like located in the periphery of a linkage component (block portion), in addition to the linkage component (block portion) of the solder fillet 5. According to one or more embodiments, the inspection portion 78 serving to extract one solder fillet image Ih from the original image data for inspection Ik configures the “solder fillet image extraction unit”.

The process subsequently selects an appropriate image frame out of the first image frame W1 and the second image frame W2, based on the size and the shape of the extracted one solder fillet image Ih, and obtains some of the inspection image data Ka to Kd with the one solder fillet image Ih provided in the selected image frame W1 or W2 (refer to FIG. 19 to FIG. 24 for the inspection image data Ka to Kd).

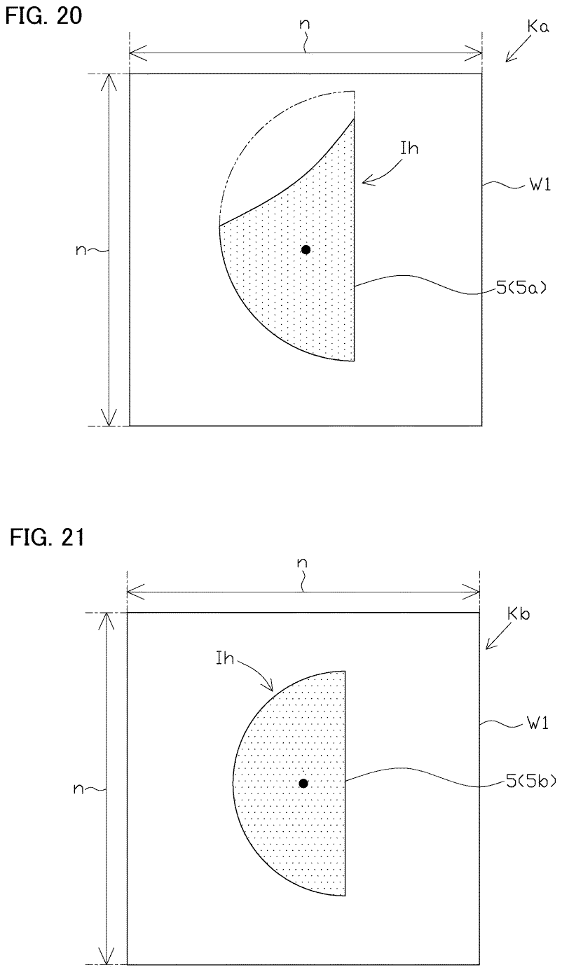

More specifically, in the case where the size of the extracted one solder fillet image Ih is larger than the size of the second image frame W2, first inspection image data Ka and Kb (as shown in, for example, FIG. 19 to FIG. 21) are obtained by pasting the extracted one solder fillet image Ih to the first image frame W1. Accordingly, the sizes (the width and the height) of the first inspection image data Ka and Kb match the sizes of the first learning data Ga and Gb. In FIG. 20, a virtual solder fillet 5 having a normal shape and a normal area is shown by a two-dot chain line for the purpose of reference.

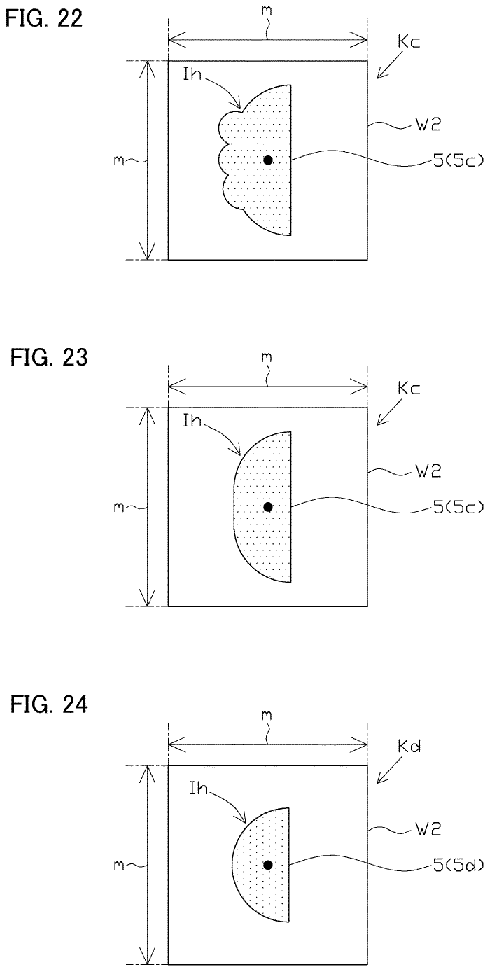

In another example, in the case where the size of the extracted one solder fillet image Ih is smaller than the size of the second image frame W2, second inspection image data Kc and Kd (as shown in, for example, FIGS. 22 to 24) are obtained by pasting the extracted one solder fillet image Ih to the second image frame W2. Accordingly, the sizes of the second inspection image data Kc and Kd match the sizes of the second learning data Gc and Gd.

Furthermore, a process of adjusting the pasting position and a process of rotating an image are performed when the one solder fillet image Ih is pasted to the image frame W1 or W2. As in the respective learning data Ga to Gd, in the respective inspection image data Ka to Kd, this causes the center or the center of gravity of the one solder fillet image Ih to match the center of the image frame W1 or W2 and causes an electronic component 6-side region to be directed in a predetermined direction in the one solder fillet image Ih.

Repeating the above series of processes of extracting one solder fillet image Ih and pasting the extracted one solder fillet image Ih to a selected image frame W1 or W2 causes the respective inspection image data Ka to Kd to be obtained from one original image data for inspection Ik. According to one or more embodiments, each of the inspection image data Ka to Kd includes inspection image data obtained based on two-dimensional data and inspection image data obtained based on three-dimensional data. According to one or more embodiments, the inspection portion 78 serving to obtain the inspection image data Ka to Kd configures the “inspection image data obtaining unit”.

A reconfiguration image data obtaining process is then performed at subsequent step S303. More specifically, in response to a command from the main controller 71, the inspection portion 78 gives each of the inspection image data Ka to Kd obtained at step S302 into an input layer of the AI model 101 or 102 corresponding to the type of the obtained inspection image data Ka to Kd. The first inspection image data Ka and Kb are input into the first AI model 101; and the second inspection image data Kc and Kd are input into the second AI model 102. The inspection image data Ka to Kd obtained based on the two-dimensional data are input into the AI models 101 and 102 corresponding to the two-dimensional data; and the inspection image data Ka to Kd obtained based on the three-dimensional data are input into the AI models 101 and 102 corresponding to the three-dimensional data. The inspection portion 78 then obtains image data that are reconfigured by the AI models 101 and 102 and that are output from respective output layers thereof, as reconfiguration image data. The reconfiguration image data obtained are stored in relation to the inspection image data Ka to Kd that are source data of the reconfiguration image data.

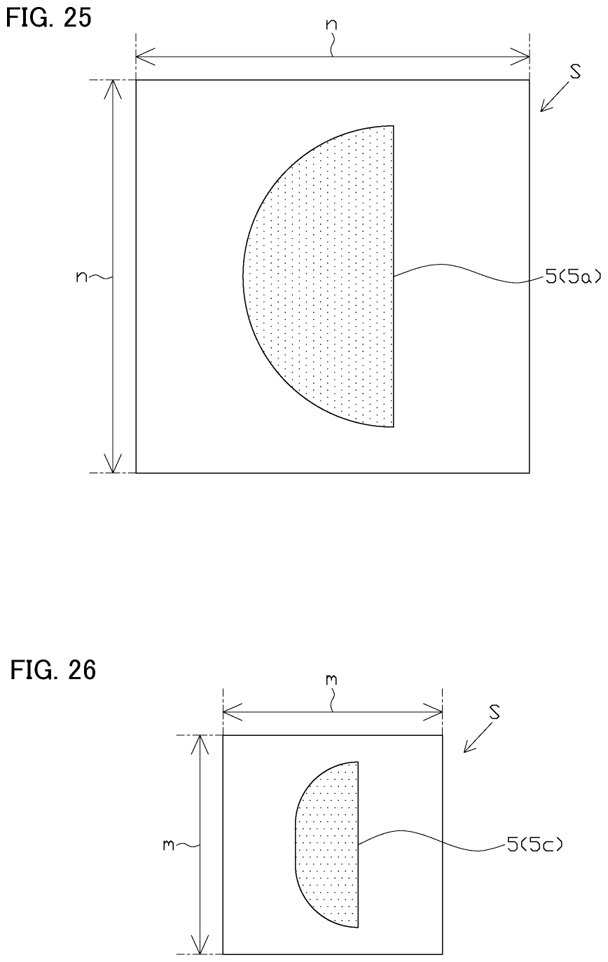

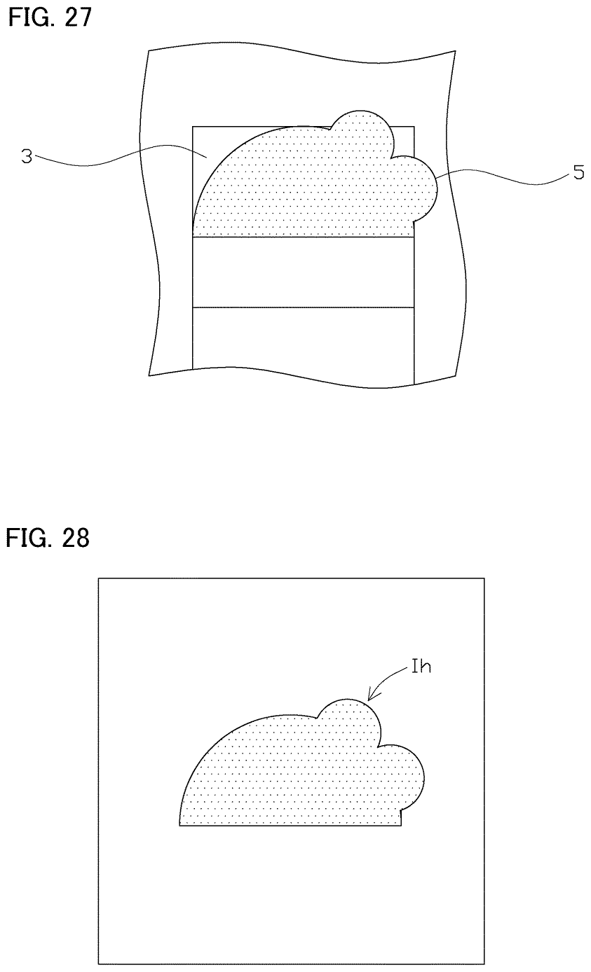

In the case of an input of the inspection image data Ka or Kc with regard to a solder fillet 5 of any inappropriate shape or the like (as shown in FIG. 20 or FIG. 22), each of the AI models 101 and 102 performs the learning described above and thereby outputs image data of a non-defective solder fillet 5 with modification of the shape or the like, as reconfiguration image data S (as shown in, for example, FIG. 25 and FIG. 26).

In the case of an input of any of the inspection image data Ka to Kd with regard to a non-defective solder fillet 5, on the other hand, each of the AI models 101 and 102 outputs image data with regard to the non-defective solder fillet 5 that is substantially identical with the input one of the inspection image data Ka to Kd, as reconfiguration image data S. The size (the width and the height) of the reconfiguration image data S matches the size of the inspection image data Ka to Kd as the source data. According to one or more embodiments, the inspection portion 78 serving to obtain the reconfiguration image data S configures the “reconfiguration image data obtaining unit”.

A defectiveness/non-defectiveness detection process based on the obtained reconfiguration image data S is then performed at step S304. In the defectiveness/non-defectiveness detection process, in response to a command from the main controller 71, the inspection portion 78 makes a comparison between the entirety of one of the inspection image data Ka to Kd obtained at step S302 described above and the entirety of the reconfiguration image data S obtained at step S303 by using the inspection image data Ka to Kd, and calculates a difference between the image data Ka to Kd and the image data S. For example, a procedure compares the dots (pixels) at specified identical coordinates between the image data Ka to Kd and the corresponding image data S and calculates the area (the number of dots) of a block of dots having a luminance value difference of not less than a predetermined value. According to one or more embodiments, the inspection portion 78 serving to make a comparison between the inspection image data Ka to Kd and the reconfiguration image data S configures the “comparison unit”. Additionally, a process of making a comparison between the inspection image data Ka to Kd and the reconfiguration image data S corresponds to the “comparison process”.

The inspection portion 78 subsequently determines whether the calculated difference is larger than a predetermined reference value. When the calculated difference is larger than the predetermined reference value, the inspection portion 78 determines the obtained inspection image data as “defective”. When the calculated difference is smaller than the predetermined reference value, on the other hand, the inspection portion 78 determines the obtained inspection image data as “non-defective”.

The inspection portion 78 performs the determination described above with regard to all the inspection image data Ka to Kd relating to each inspection target area of a printed circuit board 1. When all the inspection image data Ka to Kd are determined as “non-defective”, the inspection portion 78 determines that the inspection target area is “non-defective” and stores this result in the storage unit 57. When at least one of the inspection image data Ka to Kd is determined as “defective” as a result of the above determination performed with regard to all the inspection image data Ka to Kd relating to the inspection target area, on the other hand, the inspection portion 78 determines that the inspection target area is “defective” and stores this result in the storage unit 57.

In the case where all the inspection target areas are determined as “non-defective” as a result of the above inspection process performed with regard to all the inspection target areas in the printed circuit board 1, the solder fillet inspecting device 16 determines that the printed circuit board 1 has no abnormality in the solder fillets 5 (acceptance) and stores this result in the storage unit 57.

In the case where there is any inspection target area determined as “defective”, on the other hand, the solder fillet inspecting device 16 determines that the printed circuit board 1 has some abnormality in the solder fillets 5 (rejection) and stores this result in the storage unit 57 and notifies the outside of this result via the display unit 56 and the communication unit 58.

As described above in detail, according to one or more embodiments, each of the inspection image data Ka to Kd is obtained by providing the one solder fillet image Ih in the image frame W1 or W2. The size (the width and the height) of each of the inspection image data Ka to Kd is thus not minutely varied according to the size of the land 3 but is fixed. There is accordingly no need for providing a large number of different AI models (different identification units) corresponding to different sizes of lands 3. This configuration reduces the labor, the time and the effort of providing the AI models 101 and 102. This configuration also enables the AI models 101 and 102 to be commonly used for the lands 3 of various sizes.

Furthermore, the sizes of the respective image frames W1 and W2 for the learning data Ga to Gd are equal to the sizes of the respective image frames W1 and W2 for the inspection image data Ka to Kd. The respective sizes of the learning data Ga to Gd are equal to the respective sizes of the inspection image data Ka to Kd. When each of the inspection image data Ka to Kd is input into one of the AI models 101 and 102, this configuration enables the appropriate reconfiguration image data S corresponding to each of the inspection image data Ka to Kd to be more certainly output from the AI model and thereby ensures the more accurate defectiveness/non-defectiveness detection of the solder fillets 5. This more reliably ensures the high inspection accuracy.

Moreover, the configuration of one or more embodiments makes a comparison between the respective inspection image data Ka to Kd and the corresponding reconfiguration image data S that are reconfigured by inputting the respective inspection image data Ka to Kd into the AI model 101 or 102, and performs the defectiveness/non-defectiveness detection of the solder fillets 5, based on the results of the comparison. Accordingly, each of the image data Ka to Kd and the reconfiguration image data S to be compared with each other are related to one identical solder fillet 5. Unlike a technique of performing defectiveness/non-defectiveness detection by a comparison with a separately provided standard or criterion, this configuration does not need to set relatively mild inspection conditions for the purpose of preventing an erroneous inspection but allows for setting the stricter inspection conditions. Furthermore, the same imaging conditions for the printed circuit board 1 as an inspection object (for example, the layout position, the layout angle, and the deflection of the printed circuit board 1) and the same imaging conditions of the inspecting device 16 (for example, the illumination conditions and the angle of view of the camera) may be employed for both the image data Ka to Kd and the image data S to be compared with each other. These, in combination, enable the defectiveness/non-defectiveness detection of the solder fillets 5 to be performed with the higher accuracy.

Additionally, according to one or more embodiments, one solder fillet image Ih configuring each of the inspection image data Ka to Ke includes not only an image of a portion of a solder fillet 5 located on a land 3 but an image of a portion of the solder fillet 5 partly protruded from the land 3. This configuration enables the defectiveness/non-defectiveness detection to be adequately performed with regard to the solder fillet 5 partly protruded from the land 3 and thereby further enhances the inspection accuracy.

According to one or more embodiments, in the case where one solder fillet image Ih has a relatively small size, inspection image data Kc or Kd of a relatively small size is obtained by providing the one solder fillet image Ih in the second image frame W2 of a relatively small size. When this relatively small inspection image data Kc or Kd is input into the second AI model 102, relatively small reconfiguration image data S is output from the second AI model 102. The relatively small inspection image data Kc or Kd is then compared with the relatively small reconfiguration image data S. Compared with a configuration of using a fixed size of an image frame for any inspection image data, this configuration speeds up the process of obtaining the reconfiguration image data S and the comparison process by the inspection portion 78 and thereby further increases the inspection speed.

Furthermore, the configuration of one or more embodiments causes the directions and the positions of the respective solder fillets 5 to be substantially adjusted in the learning data Ga to Gd and in the inspection image data Ka to Kd. This configuration enables the defectiveness/non-defectiveness detection of the solder fillets 5 to be performed with high accuracy, even when a relatively small number of the learning data Ga to Gd are used for generation of the AI models 101 and 102. This configuration accordingly achieves the high inspection accuracy, while more effectively reducing the labor and the time for obtaining the AI models 101 and 102.

The present disclosure is not limited to the description of the above embodiments but may be implemented, for example, by configurations described below. The present disclosure may also be naturally implemented by applications and modifications other than those illustrated below.

(a) The configuration of the embodiments described above makes a comparison between the entirety of one of the inspection image data Ka to Kd and the entirety of the corresponding reconfiguration image data S in the defectiveness/non-defectiveness detection process at step S304.

A modified configuration may, on the other hand, make a comparison between one of the inspection image data Ka to Kd and the corresponding reconfiguration image data S with specifying only one solder fillet image Ih in the inspection image data Ka to Kd as a comparison object. In other words, this modified configuration may make a comparison between one solder fillet image Ih in one of the inspection image data Ka to Kd and an area overlapping with the one solder fillet image Ih in the reconfiguration image data S.

This modified configuration excludes the part other than the one solder fillet image Ih in the inspection image data Ka to Kd from the comparison object. This reduces the processing load in relation to the comparison between the image data Ka to Kd and the corresponding image data S, compared with the configuration of making a comparison between the entirety of one of the image data Ka to Kd and the entirety of the corresponding image data S. This modified configuration accordingly increases the speed and the efficiency of the inspection. Furthermore, this modified configuration more reliably prevents the part other than the one solder fillet image Ih in the inspection image data Ka to Kd, i.e., a part having no relation to any solder fillet 5, from affecting the defectiveness/non-defectiveness detection and thereby further enhances the inspection accuracy.

Another modified configuration may make a comparison between one of the inspection image data Ka to Kd and the corresponding reconfiguration image data S with specifying only an area relating to a solder fillet 5 in the reconfiguration image data S as a comparison object. In other words, this modified configuration may make a comparison between the area relating to a solder fillet 5 in the reconfiguration image data S and an area overlapping with the area relating to the solder fillet 5 in the inspection image data Ka to Kd. These two comparison techniques described above may be used in combination.

(b) In the process of learning the neural network 90, the configuration of the embodiments described above uses the original image data for learning Ig with regard to the printed circuit board 1 that has been accepted in the post-reflow inspection, to obtain the learning data Ga to Gd. According to a modification, the learning data Ga to Gd may be obtained, for example, by using original image data for learning with regard to a non-defective solder fillet 5, which is visually selected by an operator after printing of solder fillets 5.

According to another modification, the learning portion 77 may use image data of a virtually generated non-defective solder fillet 5 to obtain the learning data Ga to Gd.

(c) According to the embodiments described above, AI models corresponding to two-dimensional data and AI models corresponding to three-dimensional data are separately provided as the AI models 101 and 102. According to a modification, common AI models may be provided corresponding to both two-dimensional data and three-dimensional data.

Furthermore, a modified configuration may omit the second AI model 102. In this modification, the sizes of the second inspection image data Kc and Kd match the sizes of the first inspection image data Ka and Kb. This modified configuration may cause an inspection based on the inspection image data Ka to Kd to be performed by using the first AI model 101.

(d) The configuration of the AI models 101 and 102 (the configuration of the neural network 90) and the learning method thereof are not limited to those of the embodiments described above. For example, a modified configuration may process a variety of data by a normalization process or the like as needed basis in the course of a learning process of the neural network 90 or in the course of a process of obtaining the reconfiguration image data. Moreover, the structure of the neural network 90 is not limited to the structure shown in FIG. 5 but may be provided with a pooling layer subsequent to the convolution layer 93. A modified configuration may employ, for example, a different number of layers of the neural network 90, a different number of nodes in each layer, and a different connecting structure of the respective nodes.

Furthermore, according to the embodiments described above, each of the AI models 101 and 102 (the neural network 90) is the generation model having the configuration of the convolutional autoencoder (CAE). This configuration is, however, not restrictive. Each of the AI models 101 and 102 (the neural network 90) may be a generation model having the configuration of a different type of autoencoder, for example, a variational autoencoder (VAE).

The above embodiments are configured to perform learning of the neural network 90 by the error backpropagation method. This configuration is, however, not restrictive. Learning of the neural network 90 may be performed by using any of various other learning algorithms.

Moreover, the neural network 90 may be configured by a dedicated AI processing circuit, such as an AI chip. In this case, only learning information, such as parameters, may be stored in the storage unit 57. In this modification, the AI models 101 and 102 may be configured by setting the learning information, which is read out by the dedicated AI processing circuit, in the neural network 90.

Additionally, according to the embodiments described above, the control device 33 is provided with the learning portion 77 and is configured to perform learning of the neural network 90 inside of the control device 33. This configuration is, however, not restrictive. For example, a modified configuration with omission of the learning portion 77 may cause learning of the neural network 90 to be performed outside of the control device 33 and may store the AI models 101 and 102 learnt outside (the learnt neural network 90) in the storage unit 57.

(e) The configuration of the embodiments described above obtains both two-dimensional data and three-dimensional data as the original image data for inspection Ik. A modified configuration may obtain only either one of the two-dimensional data and the three-dimensional data. This modified configuration may also be provided with only AI models corresponding to the obtained data out of the two-dimensional data and the three-dimensional data as the AI models 101 and 102.

(f) The configuration of the embodiments described above pastes one solder fillet image Ih to one of the image frames W1 and W2, so as to obtain the inspection image data Ka to Kd. A modified configuration may, however, obtain the inspection image data Ka to Kd by a procedure described below. In the process of extracting an image of a linkage component (block portion) in each specified area occupied by a solder fillet 5 as one solder fillet image Ih, this procedure may first extract one solder fillet image Ih and a peripheral portion thereof to obtain an extracted image having the same size as the size of the image frame W1 or W2. The procedure may subsequently obtain the inspection image data Ka to Kd by replacing values of respective pixels of the peripheral portion in the extracted image with one fixed value (for example, the luminance and the height are set equal to “0”). The modified configuration may obtain the learning data Ga to Gd by employing a similar technique.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### REFERENCE SIGNS LIST

1 . . . printed circuit board, 3 . . . land, 5 . . . solder fillet, 6 . . . electronic component, 16 . . . solder fillet inspecting device, 32d . . . camera (image data capturing unit or image device), 78 . . . inspection portion (inspection image data obtaining unit, reconfiguration image data obtaining unit, comparison unit, solder fillet image extraction unit), 90 . . . neural network, 91 . . . encoder portion (encoding unit), 92 . . . decoder portion (decoding unit), 101 . . . first AI model (identification unit), 102 . . . second AI model (second identification unit), Ih . . . one solder fillet image, W1 . . . first image frame (image frame), W2 . . . second image frame

What is claimed is:

1. A solder fillet inspecting device comprising:
an imaging device that captures image data of an inspection target area in a printed circuit board that includes a solder fillet formed to solder an electronic component to the printed circuit board;
a first Artificial Intelligence (AI) model generated by learning of a neural network using only image data of a non-defective solder fillet as first learning data, wherein
the neural network comprises an encoder configured to extract a feature quantity from input image data and a decoder configured to reconfigure the input image data from the feature quantity; and
a control device that:
obtains, as an inspection object, inspection image data that includes an image of the solder fillet based on the image data captured by the imaging device,
obtains reconfiguration image data by inputting the inspection image data into the first AI model,
makes a comparison between the inspection image data and the reconfiguration image data, and
detects defectiveness/non-defectiveness of the solder fillet based on a comparison result, wherein
the first learning data is generated by placing one solder fillet image that indicates a solder fillet corresponding to one land, in a first image frame having a larger size than a size of the one solder fillet image, and
the control device obtains the inspection image data that has a size identical with a size of the first learning data and that is generated by placing the one solder fillet image extracted from the image data captured by the imaging device, in an image frame having a size identical with the size of the first image frame for the first learning data.

2. The solder fillet inspecting device according to claim 1, wherein
the control device further:
extracts the one solder fillet image that constitutes the inspection image data, from the image data captured by the imaging device, and
specifies an area occupied by the solder fillet in the image data captured by the imaging device, and extracts an image of a linkage component in the specified area, as the one solder fillet image that constitutes the inspection image data.

3. The solder fillet inspecting device according to claim 1, further comprising:
a second AI model generated by learning of a neural network using only image data of a non-defective solder fillet as second learning data, wherein
the neural network comprises an encoder configured to extract a feature quantity from input image data and a decoder configured to reconfigure the input image data from the feature quantity, and
the second learning data is generated by placing the one solder fillet image in a second image frame having such a size that is larger than the size of the one solder fillet image and that is smaller than the size of the first image frame for the first learning data, and
in a case where the size of the one solder fillet image extracted from the image data captured by the imaging device is smaller than the size of the second image frame, the control device:
obtains the inspection image data that has a size identical with a size of the second learning data and that is generated by placing the one solder fillet image in the second image frame,
obtains the reconfiguration image data by inputting the obtained inspection image data into the second AI model, and
makes the comparison between the inspection image data and the reconfiguration image data.

4. The solder fillet inspecting device according to claim 1, wherein
the first learning data and the inspection image data are set such that a center or a center of gravity of the one solder fillet image matches a center of the first image frame and such that an electronic component-side region in the one solder fillet image is directed in a predetermined direction.

5. The solder fillet inspecting device according to claim 1, wherein
the control device makes the comparison between the inspection image data and the reconfiguration image data with only the one solder fillet image in the inspection image data as a comparison object.

6. A solder fillet inspecting method comprising:
an image data capturing process of capturing image data of an inspection target area in a printed circuit board that includes a solder fillet formed to solder an electronic component to the printed circuit board;
an inspection image data obtaining process of obtaining, as an inspection object, inspection image data that includes an image of the solder fillet based on the image data captured in the image data capturing process;
a reconfiguration image data obtaining process of obtaining reconfiguration image data by inputting the inspection image data into a first Artificial Intelligence (AI) model, wherein
the first AI model is generated by learning of a neural network using only image data of a non-defective solder fillet as first learning data, and
the neural network comprises an encoder configured to extract a feature quantity from input image data and a decoder configured to reconfigure the input image data from the feature quantity;
a comparison process of making a comparison between the inspection image data and the reconfiguration image data; and
a detection process of detecting defectiveness/non-defectiveness of the solder fillet based on a comparison result, wherein
the first learning data is generated by placing one solder fillet image that indicates a solder fillet corresponding to one land, in a first image frame having a larger size than a size of the one solder fillet image, and
the inspection image data obtaining process obtains the inspection image data that has a size identical with a size of the first learning data and that is generated by placing the one solder fillet image extracted from the image data captured in the image data capturing process, in an image frame having a size identical with the size of the first image frame for the first learning data.
